(19) United States
(12) Patent Application Publication
(10) Pub. No.: US 2016/0035899 A1
(43) Pub. Date: Feb. 4, 2016

(54) BIASING A SILICON-ON-INSULATOR (SOI) SUBSTRATE TO ENHANCE A DEPLETION REGION

(71) Applicant: QUALCOMM Incorporated, San Diego, CA (US)

(72) Inventors: Jiri Stulemeijer, Heerlen (NL); Arnold Den Dekker, Beuningen (NL); Maurice Adrianus de Jongh, Nijmegen (NL)

(21) Appl. No.: 14/447,068

(22) Filed: Jul. 30, 2014

(51) Int. Cl. H01L 29/786; H03K 17/687; H03K 17/12

(52) U.S. Cl. CPC H01L 29/78606; H01L 29/78603; H01L 29/78651; H03K 17/122; H03K 17/687; H03K 2017/6875

(57) ABSTRACT

A device includes a silicon-on-insulator (SOI) substrate comprising a bulk silicon (Si) substrate, a buried oxide layer over the bulk Si substrate and a silicon device layer over the buried oxide layer, a first substrate tap and a second substrate tap located in the buried oxide layer and the silicon device layer, the first and second substrate taps in contact with the bulk Si substrate, and an initial depletion region located in the bulk Si substrate below the buried oxide layer and associated with at least one of the first substrate tap and the second substrate tap, the first substrate tap and the second substrate tap configured to increase the initial depletion region based on an applied bias voltage.

### BACKGROUND

1. Field

The present disclosure relates generally to electronics, and more specifically to semiconductor devices.

2. Background

A highly resistive silicon substrate can be used for the fabrication of large signal radio frequency (RF) devices, such as antenna impedance matching and tuning circuits. Examples of technologies using high ohmic silicon substrates include, for example, silicon-on-insulator (SOI), integrated passive devices (IPD) and some micro electrical mechanical systems (MEMS) devices.

The high ohmic substrate reduces non-linear conduction and reactance in the substrate by reducing carrier densities in the substrate. Additionally, the problem of surface conduction on high ohmic substrates has been addressed to a degree. This can be done by various substrate treatment steps including, for example, high dose ion implants and/or deposition of a trap-rich layer or an amorphous silicon layer. In all of these methods, the Fermi level at the surface of the material is pinned roughly at mid bandgap.

In the bulk of the substrate, the Fermi level is determined by the residual doping level present in the bulk substrate. A difference in electrical potential between the surface and the bulk of the substrate will result in a surface depletion layer formed on the surface of the bulk substrate. Typically, for a 1 kOhm*cm substrate the built-in voltage difference between the surface and the bulk substrate is around 170 mV, resulting in a surface depletion layer of around 4 um thick. The built-in voltage results from a difference in Fermi level between the mid-bandgap pinning of the Fermi level at the top of the substrate and the Fermi level of the bulk of the substrate. It is the combination of the suppression of the surface conductance and the created depletion layer that provides the improvement in linearity for the above-mentioned substrate treatment methods.

However, these prior techniques are confined to the surface of the substrate and have shortcomings.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a block diagram showing a wireless communication device in which the exemplary techniques of the present disclosure may be implemented.

FIG. 2 is a block diagram showing the components of FIG. 1 that comprise a radio frequency (RF) front end.

FIG. 3A is a schematic diagram showing an exemplary embodiment of a system for biasing a silicon-on-insulator substrate to enhance a depletion region.

FIG. 3B is a schematic diagram showing an alternative exemplary embodiment of a system for biasing a silicon-on-insulator substrate to enhance a depletion region.

FIGS. 4A and 4B are diagrams illustrating an exemplary embodiment of the enhancement of a depletion layer using a bias voltage.

FIG. 5 is a schematic diagram showing an alternative exemplary embodiment of a system for biasing a silicon-on-insulator substrate to enhance a depletion region.

FIG. 6 is a schematic diagram showing an alternative exemplary embodiment of a system for biasing a silicon-on-insulator substrate to enhance a depletion region.

FIG. 7 is a schematic diagram showing an exemplary embodiment of a system for biasing a silicon-on-insulator substrate to enhance a depletion region including semiconductor devices.

FIG. 8 is a plan view showing a surface of an uppermost device layer of FIG. 7.

FIG. 9A is a schematic diagram showing an alternative exemplary embodiment of a system for biasing a silicon-on-insulator substrate to enhance a depletion region.

FIG. 9B is a schematic diagram showing a plan view of the exemplary embodiment of the system for biasing a silicon-on-insulator substrate to enhance a depletion region of FIG. 9A.

FIG. 10 is a flow chart showing an exemplary embodiment of a method for biasing a silicon-on-insulator substrate to enhance a depletion region.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

The term “content” may also include files having executable content, such as: object code, scripts, byte code, markup language files, and patches. In addition, “content” referred to herein, may also include files that are not executable in nature, such as documents that may need to be opened or other data files that need to be accessed.

As used herein, the terms “depletion layer” and “depletion region” are used to describe an insulating region within a conductive, doped semiconductor material where the mobile charge carriers have diffused away, or have been forced away by an electric field. The only elements left in the depletion region are ionized donor or acceptor impurities. Generally, the term “depletion layer” is used in a two-dimensional sense to define a “depletion layer width” and the term “depletion region” is used in a three-dimensional sense to define a “depletion region volume” and a depletion region may include a depletion layer.

Exemplary embodiments of the disclosure are directed toward biasing a SOI substrate to enhance a depletion region. In an exemplary embodiment, biasing the SOI substrate can generate and enhance a depletion region in the bulk substrate away from the surface of the substrate. The depletion region helps to linearize the performance of an RF device fabricated on the surface of the substrate above the depletion region.

In the description below, doping levels and doping polarity can depend on a number of different implementation factors and can be exchanged from that described. For example, N-type material layers can be exchanged with P-type material layers, simultaneous with P-type material layers being exchanged with N-type material layers.

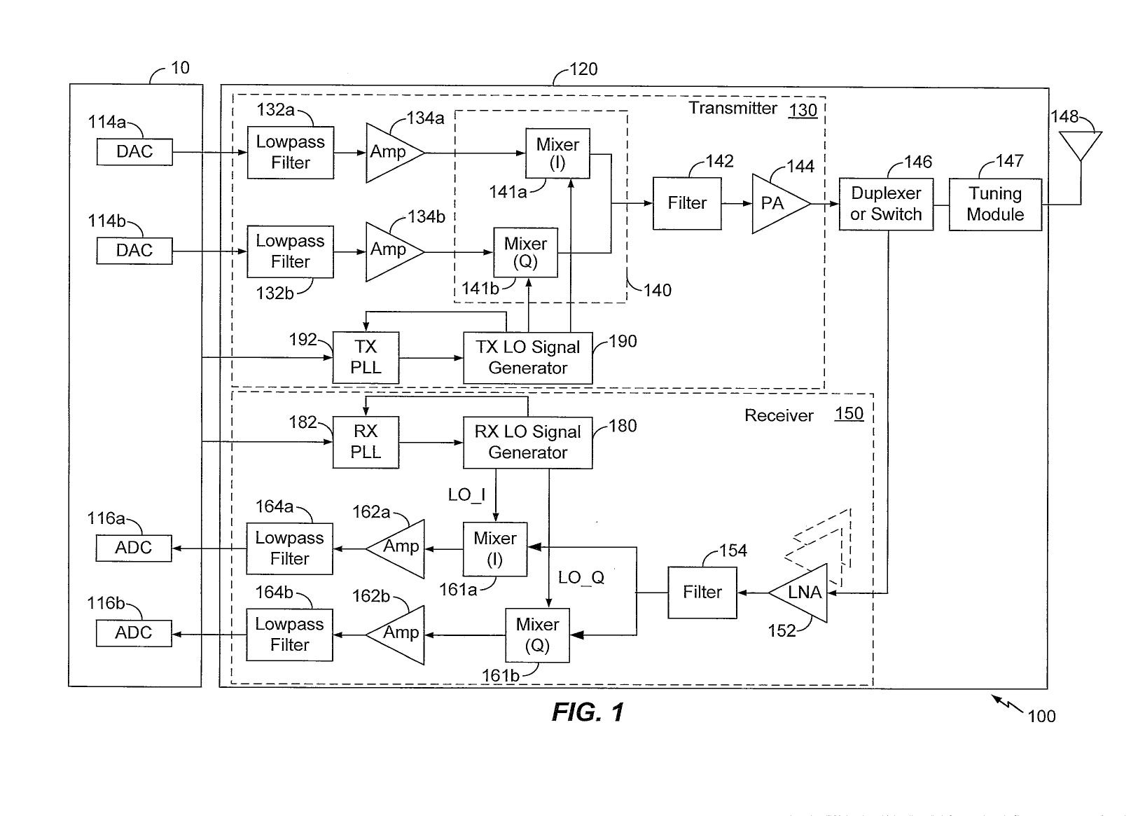

FIG. 1 is a block diagram showing a wireless communication device 100 in which the exemplary techniques of the present disclosure may be implemented. FIG. 1 shows an example of a transceiver 100. In general, the conditioning of the signals in a transmitter 130 and a receiver 150 may be performed by one or more stages of amplifier, filter, upconverter, downconverter, etc. These circuit blocks may be arranged differently from the configuration shown in FIG. 1. Furthermore, other circuit blocks not shown in FIG. 1 may also be used to condition the signals in the transmitter and receiver. Unless otherwise noted, any signal in FIG. 1, or any other figure in the drawings, may be either single-ended or differential. Some circuit blocks in FIG. 1 may also be omitted.

In the example shown in FIG. 1, wireless device 100 generally comprises a transceiver 120 and a data processor 110. The data processor 110 may include a memory (not shown) to store data and program codes, and may generally comprise analog and digital processing elements. The transceiver 120 includes a transmitter 130 and a receiver 150 that support bi-directional communication. In general, wireless device 100 may include any number of transmitters and/or receivers for any number of communication systems and frequency bands. All or a portion of the transceiver 120 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 1, transmitter 130 and receiver 150 are implemented with the direct-conversion architecture.

In the transmit path, the data processor 110 processes data to be transmitted and provides in-phase (I) and quadrature (Q) analog output signals to the transmitter 130. In an exemplary embodiment, the data processor 110 includes digital-to-analog-converters (DAC's) 114a and 114b for converting digital signals generated by the data processor 110 into the I and Q analog output signals, e.g., I and Q output currents, for further processing.

Within the transmitter 130, lowpass filters 132a and 132b filter the I and Q analog transmit signals, respectively, to remove undesired images caused by the prior digital-to-analog conversion. Amplifiers (Amp) 134a and 134b amplify the signals from lowpass filters 132a and 132b, respectively, and provide I and Q baseband signals. An upconverter 140 upconverts the I and Q baseband signals with I and Q transmit (TX) local oscillator (LO) signals from a TX LO signal generator 190 and provides an upconverted signal. A filter 142 filters the upconverted signal to remove undesired images caused by the frequency upconversion as well as noise in a receive frequency band. A power amplifier (PA) 144 amplifies the signal from filter 142 to obtain the desired output power level and provides a transmit RF signal. The transmit RF signal is routed through a duplexer or switch 146 and a tuning module 147 and transmitted via an antenna 148.

In the receive path, antenna 148 receives communication signals and provides a received RF signal, which is routed through the tuning module 147, through the duplexer or switch 146 and provided to a low noise amplifier (LNA) 152. The duplexer 146 is designed to operate with a specific RX-to-TX duplexer frequency separation, such that RX signals are isolated from TX signals. The received RF signal is amplified by LNA 152 and filtered by a filter 154 to obtain a desired RF input signal. Downconversion mixers 161a and 161b mix the output of filter 154 with I and Q receive (RX) LO signals (i.e., LO_I and LO_Q) from an RX LO signal generator 180 to generate I and Q baseband signals. The I and Q baseband signals are amplified by amplifiers 162a and 162b and further filtered by lowpass filters 164a and 164b to obtain I and Q analog input signals, which are provided to data processor 110. In the exemplary embodiment shown, the data processor 110 includes analog-to-digital-converters (ADC's) 116a and 116b for converting the analog input signals into digital signals to be further processed by the data processor 110.

In FIG. 1, TX LO signal generator 190 generates the I and Q TX LO signals used for frequency upconversion, while RX LO signal generator 180 generates the I and Q RX LO signals used for frequency downconversion. Each LO signal is a periodic signal with a particular fundamental frequency. A phase locked loop (PLL) 192 receives timing information from data processor 110 and generates a control signal used to adjust the frequency and/or phase of the TX LO signals from LO signal generator 190. Similarly, a PLL 182 receives timing information from data processor 110 and generates a control signal used to adjust the frequency and/or phase of the RX LO signals from LO signal generator 180.

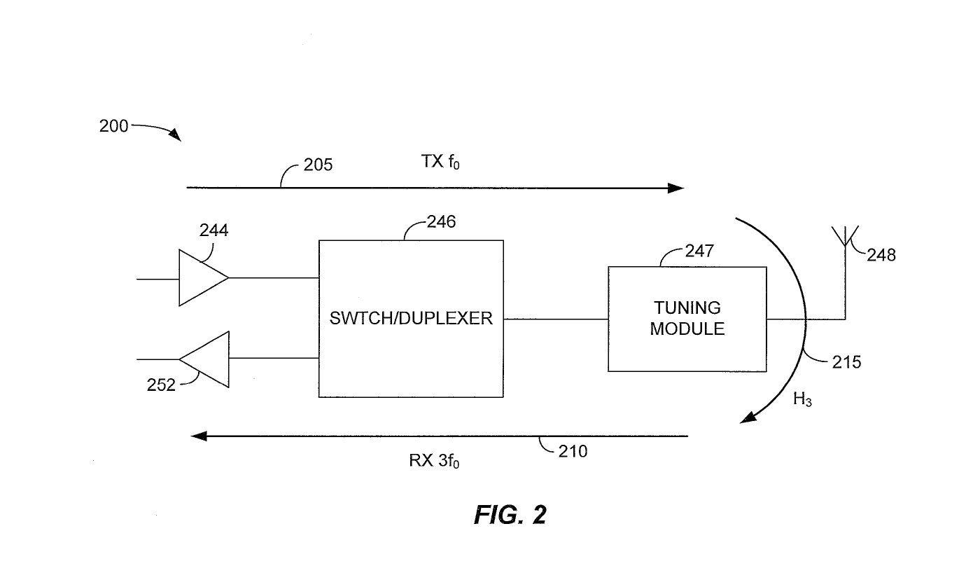

FIG. 2 is a block diagram showing the components of FIG. 1 that comprise a radio frequency (RF) front end. In an exemplary embodiment, the RF front end 200 comprises a power amplifier 244 and a low noise amplifier 252 coupled to a duplexer or switch 246. The duplexer or switch 246 is coupled to a tuning module 247. The tuning module 247 is coupled to an antenna 248. Exemplary embodiments of the disclosure can be implemented to fabricate at least portions of the tuning module 247. Generally, the tuning module 247 is designed to match the impedance of the power amplifier 244 to the impedance of the antenna 248, thus optimizing transmit power. In some communication standards, simultaneous transmission and reception may occur at harmonically related frequencies. For example, the arrow 205 indicates a transmit frequency of TX f0 and the arrow 210 indicates a receive frequency of RX 3f0, which is the third harmonic of the transmit frequency TX f0. As a result, third order harmonic distortion, H3, shown using arrow 215, can occur through the tuning module 247. Therefore, to minimize this distortion, it is desirable to minimize non-linearities in the tuning module 247.

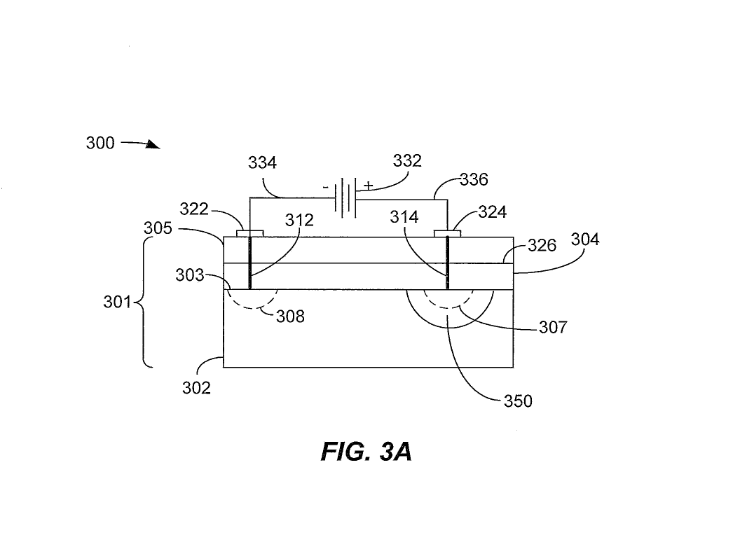

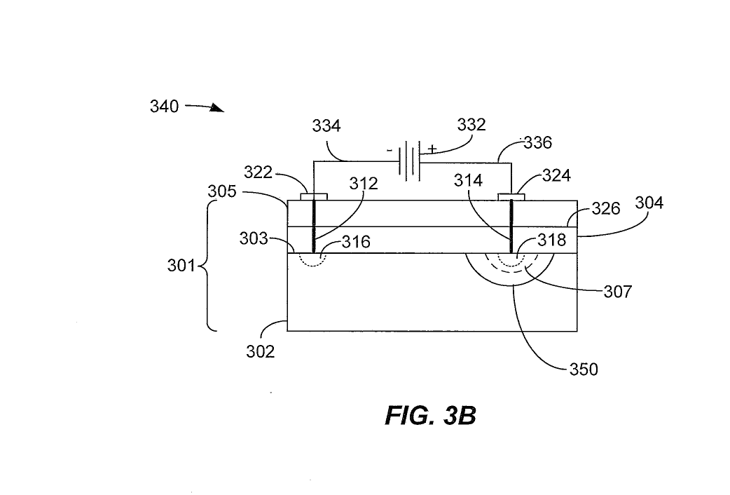

FIG. 3A is a schematic diagram showing an exemplary embodiment of a system for biasing a silicon-on-insulator substrate to enhance a depletion region. In an exemplary embodiment, the system 300 comprises silicon-on-insulator (SOI) substrate 301 having a bulk Si layer 302, a buried oxide layer 304 and a silicon device layer 305. The bulk Si 302 can also be referred to as a “handle wafer.” In an exemplary embodiment, the bulk Si 302 can be doped p-type (P−) material. The buried oxide layer 304 can be formed on the surface of the bulk Si 302 and the silicon device layer 305 can be formed over the buried oxide layer 304 according to techniques known in the art. In an exemplary embodiment, the thickness of the buried oxide layer 304 may range from approximately 400 nanometers (nm) thick to approximately 1000 nm thick and the thickness of the silicon device layer 305 may range from approximately 50 nanometers (nm) thick to approximately 1000 nm thick. The thickness of the buried oxide layer 304 and the silicon device layer 305 is determined based on a number of factors, including, for example, the amount of isolation desired between a device formed in the Si device layer 305 above the buried oxide layer 304 and the bulk Si 302.

In an exemplary embodiment, substrate taps 312 and 314 can be formed in the Si device layer 305 and the buried oxide layer 304 down to the surface 303 of the bulk Si 302. In an exemplary embodiment, an opening can be formed in the Si device layer 305 and the buried oxide layer 304 down to the surface 303 of the bulk Si 302 by etching, drilling, or other techniques. The opening can then be filled using an electrically conductive material to form the substrate taps 312 and 314. Conductive material that can be used to form the substrate taps 312 and 314 includes, for example, metal, such as aluminum, copper, chromium, tungsten, titanium, or other metals or metal alloys, or a silicon or polysilicon material. The silicon or polysilicon may be undoped or doped.

In an exemplary embodiment, electrical connection between the substrate taps 312 and 314 and the bulk Si 302 can be formed by creating any form of a rectifying contact, such as, for example, a tunneling contact, a Schottky contact, or any other type of rectifying contact known to those having ordinary skill in the art. A rectifying contact is one that causes an initial depletion region 307 to be created in the bulk Si 302 in the vicinity of the contact. Alternatively, in an exemplary embodiment, the rectifying contact can be formed using N-doped semiconductor material, such as silicon or polysilicon, to create a PN junction between the substrate tap 314 and the P-type bulk Si 302.

In an exemplary embodiment, the substrate tap 312 is connected to an electrical contact 322, and the substrate tap 314 is connected to an electrical contact 324. In an exemplary embodiment, the electrical contacts 322 and 324 can be part of a metal layer (not shown) that can be formed above the Si device layer 305. A voltage source 332 is coupled to the electrical contact 322 over connection 334 and to the electrical contact 324 over connection 336.

In an exemplary embodiment, the voltage source 332 can cause an electrical potential difference to be created between the substrate tap 312 and the substrate tap 314, causing an enhanced depletion region 350 to be formed in the bulk Si 302 between the substrate tap 312 and the substrate tap 314. In this manner, the bulk Si 302 between the substrate tap 312 and the substrate tap 314 is electrically biased to create the enhanced depletion region 350 in the bulk Si 302. In an exemplary embodiment, the initial depletion regions 307 and 308 are formed when a metal of the substrate tap 312 or 314 is in contact with the substrate P− material, thus forming the initial depletion regions 307 and 308 by the rectifying contact between the substrate tap 312 and the bulk Si 302 and between the substrate tap 314 and the bulk Si 302. In an exemplary embodiment, electrically biasing the substrate tap 312 and the substrate tap 314 increases one of the initial depletion regions 307 or 308 to form the enhanced depletion region 350.

In an exemplary embodiment, the substrate tap 312 and the substrate tap 314 can be formed using a metal or metal alloy material that creates a rectifying contact with the bulk Si 302. The polarity of the voltage applied by the voltage source 332 will determine at which of the two substrate taps 312 and 314 the enhanced depletion region 350 will grow. In an exemplary embodiment, the (+) voltage is applied to the substrate tap 314 and the (−) voltage is applied to the substrate tap 312 such that the enhanced depletion region 350 expands near the substrate tap 314.

The bias voltage applied by the voltage source 332 can be adjusted, which together with the difference in Fermi level (Ef) between the substrate tap 314 and the bulk Si 302 defines the size of the enhanced depletion region 350. The substrate tap 314 is of different material than the rest of the surface 303, which is the reason that the enhanced depletion region 350 grows in the bulk Si 302 below the substrate tap 314 and not along the entire wafer surface 303. Without biasing the substrate, the initial depletion layer thickness results from the difference in Fermi level in the bulk Si 302 with either the Fermi level in the substrate tap 312 or 314 in case of a silicon or polysilicon substrate taps or with the difference in Fermi level between the bulk Si 302 and the work function of the metal in the case of metal substrate taps.

In an exemplary embodiment, when circuit components are placed above the enhanced depletion region 350 created by the electrically biased substrate, any non-linear substrate parasitics in the bulk Si are reduced with respect to the previously mentioned substrate treatment methods when sufficient bias voltage is applied.

In an exemplary embodiment, an optional surface depletion layer (not shown) can be formed at the surface 303 of the bulk Si 302 using a known substrate treatment method.

FIG. 3B is a schematic diagram showing an alternative exemplary embodiment of a system for biasing a silicon-on-insulator substrate to enhance a depletion region. In an exemplary embodiment, the system 340 is similar to the system 300 described in FIG. 3A. Elements in FIG. 3B that are similar to elements in FIG. 3A are numbered the same and will not be described again in detail.

In FIG. 3B, optional contact regions 316 and 318 can also be formed in the bulk Si in the vicinity of and in contact with the substrate taps 312 and 314, respectively. In an exemplary embodiment, the contact region 316 may be doped to be P-type and the contact region 318 may be doped to be N-type. In an exemplary embodiment, the contact region 316 can be heavily doped P+ and the contact region 318 may be heavily doped N+. Implanting of donor or acceptor ions into the bulk Si 302 using accelerated ions provides an exemplary means to dope the bulk Si 302 near the substrate taps 312 and 314 to further enhance the electrical contact between the substrate taps 312 and 314 and the bulk Si 302. In this exemplary embodiment, the contact region 316 is doped P+ and the contact region 318 is doped N+. Alternatively, other ways of doping the contact regions 316 and 318 can be used to enhance the electrical contact between the substrate taps 312 and 314 and the bulk Si 302. For example, in an exemplary embodiment, the substrate taps 312 and 314 can be formed using any of silicon, polysilicon, or metal. In an exemplary embodiment in which the substrate taps 312 and 314 are formed using undoped polysilicon, doping the undoped polysilicon can then be done by implanting the polysilicon with a dopant, which then can diffuse from the polysilicon substrate taps 312 and 314 into the bulk Si 302, forming the contact regions 316 and 318.

In an exemplary embodiment, the substrate tap 312 is connected to an electrical contact 322, and the substrate tap 314 is connected to an electrical contact 324. In an exemplary embodiment, the electrical contacts 322 and 324 can be part of a metal layer (not shown) that can be formed above the Si device layer 305. A voltage source 332 is coupled to the electrical contact 322 over connection 334 and to the electrical contact 324 over connection 336.

In an exemplary embodiment, the voltage source 332 can cause an electrical potential difference to be created between the substrate tap 312 and the substrate tap 314, biasing the P-N junction formed between the contact region 318 and the bulk Si 302. In this manner, the P-N junction between the contact region 318 and the bulk Si 302 is electrically biased to enhance the initial depletion region 307 so as to create the enhanced depletion region 350 in the bulk Si 302. In an exemplary embodiment, the substrate tap 314 should have a doping (N-type) of the opposite polarity from the doping of the substrate (P-type), so that in this example, the substrate tap 314 can be doped N type. Alternatively, the substrate tap 312 and the substrate tap 314 can be formed using a metal or metal alloy material that creates a contact with the doped regions 316 and 318, respectively. The polarity of the voltage applied by the voltage source 332 will determine whether the initial depletion region 307 will shrink or increase to form depletion region 350. In an exemplary embodiment, the (+) voltage is applied to the substrate tap 314 and the (−) voltage is applied to the substrate tap 312 such that the enhanced depletion region 350 expands near the substrate tap 314.

The thickness of the initial depletion region 307 is determined by the difference in Fermi level between the N+ doped contact region 318 and the P− bulk Si substrate 302. This thickness is enhanced by the applied bias supplied by the voltage source 332 to form the enhanced depletion region 350. The substrate tap 314 is of different material than the rest of the surface 303, which is the reason that the enhanced depletion region 350 grows in the bulk Si 302 below the substrate tap 314 and not along the entire wafer surface 303.

In an exemplary embodiment in which the optional contact regions 316 and 318 are implemented, the enhanced depletion region 350 is formed in the bulk Si 302 at one of the two substrate taps 312 or 314. In this exemplary embodiment, the enhanced depletion region 350 is formed around the substrate tap 314. In an exemplary embodiment, the enhanced depletion region 350 is formed below the substrate tap and contact region that has a polarity opposite the polarity of the substrate. In an exemplary embodiment, the enhanced depletion region 350 is formed below the substrate tap 314 because, in this embodiment, the polarity (N-type) of the contact region 318 is different than the polarity (P-type) of the bulk Si 302.

In an exemplary embodiment, when circuit components are placed above the enhanced depletion region 350 created by the electrically biased substrate, any non-linear substrate parasitics in the bulk Si are reduced with respect to the previously mentioned substrate treatment methods when sufficient bias voltage is applied.

In an exemplary embodiment, the effect of biasing the substrate taps 312 and 314 can be enhanced by implanting the bulk Si 302 at the substrate taps 312 and 314 using the oppositely doped implant regions 316 and 318 to create ohmic contact between the substrate taps 312 and 314 and the bulk Si 302. Without biasing the substrate, the initial depletion layer thickness results from the difference in Fermi level in the bulk Si 302 with either the Fermi level in the substrate tap 312 or 314, or in the contact region 316 or 318, when present.

In an exemplary embodiment, a surface depletion layer (not shown) can be formed at the surface of the bulk Si 302 using a known substrate treatment method.

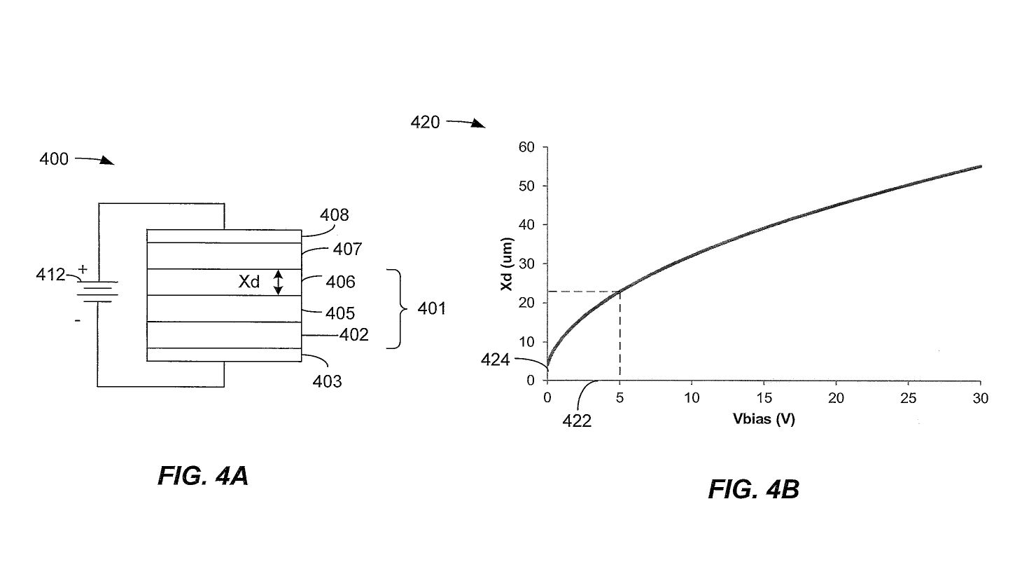

FIGS. 4A and 4B are diagrams illustrating an exemplary embodiment of the enhancement of a depletion layer using a bias voltage.

FIG. 4A is a two-dimensional drawing of a semiconductor structure having a substrate 401, and a metal material 403, such as an electrical contact, formed on the substrate 401. In an exemplary embodiment, the substrate 401 may comprise a heavily doped (P+) P-type material 402, a lightly doped (P−) P-type material 405, and may have a depletion layer 406. A lightly doped (N−) N-type material layer 407 is located over the substrate 401, and a metal material 408, such as an electrical contact is located over the lightly doped (N+) N-type material layer 407. A voltage source 412 is coupled to the electrical material and generates a bias voltage.

FIG. 4B is a graph 420 showing a relationship between bias voltage and the depletion layer of FIG. 4A. The horizontal axis 422 shows bias voltage in volts (V) and the vertical axis 424 shows thickness (Xd) of the depletion layer 406 in micrometers (um). The thickness (Xd) of the depletion layer 406 can be adjusted within a range of bias voltage.

In an exemplary embodiment, the substrate 401 can be a P-type, 1 kOhm*cm high ohmic substrate and the metal material 408 can be biased to approximately +5V using a voltage source 412 with respect to the metal material 403. This will result in a depletion layer 406 between the N-type material and the P-type material having a thickness (Xd) of about 23 um. Although the depletion layer 406 is described in FIGS. 4A and 4B as a two-dimensional structure and the enhanced depletion region 350 is described in FIGS. 3A and 3B as a three-dimensional structure, the enhanced depletion region 350 in FIG. 3A and FIG. 3B is of the same order of magnitude (for example, within 1/10× to 10×) as the depletion layer 406 in FIG. 4A.

Carrier density: ρ=1 kΩ*cm [symbol] N_{A}=1.3×10¹³ cm⁻³ Eq. 1

Constants: q=1.9×10⁻¹⁹ C, ε₀=8.85×10¹⁴F·cm⁻¹, εᵣ=11.9 Eq. 2

$$Depletion layer thickness \text{:} {x}_{d} = \sqrt{\frac{2 {ɛ}_{0} {ɛ}_{r} ( {E}_{f} + {V}_{bias} )}{q {N}_{A}}} \qquad Eq . 3$$

x_{d}=Depletion layer thickness, ε₀=Permittivity of vacuum, εᵣ=relative permittivity, E_{f}=Fermi level, V_{bias}=Bias voltage, q=electron charge, N_{A}=Acceptor density.

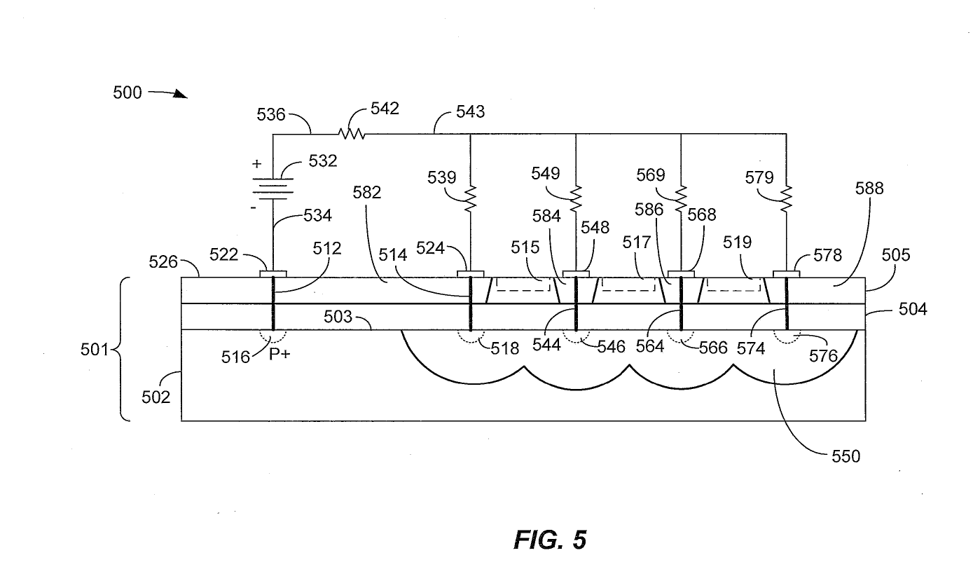

FIG. 5 is a schematic diagram showing an alternative exemplary embodiment of a system for biasing a silicon-on-insulator substrate to enhance a depletion region. In an exemplary embodiment, the system 500 comprises a SOI substrate 501 having a bulk Si layer 502, a buried oxide layer 504 and a device layer 505. The bulk Si 502 can also be referred to as a “handle wafer.”.” In an exemplary embodiment, the device layer 505 can comprise one or more silicon, metal, or other epitaxial semiconductor material layers that can be deposited, grown, sputtered, or otherwise formed over the surface of the buried oxide layer 504. In an exemplary embodiment, radio frequency (RF) devices 515, 517 and 519 can be fabricated in one or more of the device layers 505. In an exemplary embodiment, isolation regions 582, 584, 586 and 588 can be formed between and adjacent the devices 515, 517 and 519. In an exemplary embodiment, the isolation regions 582, 584, 586 and 588 can be formed by a process referred to as shallow trench isolation (STI) whereby portions of the device layers 505 away from the devices 515, 517 and 519 are removed by, for example, etching, and are then back-filled using an insulating material, such as, for example, silicon oxide. This creates isolation regions 582, 584, 586 and 588 through which the substrate taps 512, 514, 544, 564 and 574 extend.

In an exemplary embodiment, the bulk Si 502 can be doped P-type (P−). The buried oxide layer 504 and the device layer 505 can be formed on the surface of the bulk Si 502 according to techniques known in the art.

In an exemplary embodiment, substrate taps 512, 514, 544, 564 and 574 can be formed in the buried oxide layer 504 as described above. In an exemplary embodiment, the substrate taps 512, 514, 544, 564 and 574 extend through the isolation regions 582, 584, 586 and 588. Alternatively, the substrate taps 512, 514, 544, 564 and 574 may also extend through the device layers 505 in areas where there are no isolation regions 582, 584, 586 and 588. In an exemplary embodiment, the substrate taps 512, 514, 544, 564 and 574 can be formed by etching an opening through the isolation regions 582, 584, 586 and 588 and the buried oxide layer 504 down to, or partially past, the interface where the buried oxide layer 504 meets the bulk Si 502 so that the substrate taps 512, 514, 544, 564 and 574 contact the surface 503 bulk Si 502.

Optional contact regions 516, 518, 546, 566 and 576 can be formed in the bulk Si 502 proximate to the substrate taps 512, 514, 544, 564 and 574, respectively.

In an exemplary embodiment, the contact region 516 is doped to be P-type and the contact regions 518, 546, 566 and 576 are doped to be N-type. In an exemplary embodiment, the contact regions 516 is heavily doped P+ and the contact regions 518, 546, 566 and 576 are heavily doped N+. However, this doping can be reversed depending on implementation.

In an exemplary embodiment, the substrate tap 512 is connected to an electrical contact 522, the substrate tap 514 is connected to an electrical contact 524, the substrate tap 544 is connected to an electrical contact 548 the substrate tap 564 is connected to an electrical contact 568, and the substrate tap 574 is connected to an electrical contact 578. The electrical contacts 522, 524, 548, 568 and 578 can be part of a metal layer (not shown) that can be formed over the surface 526 of the device layers 505.

A voltage source 532 is coupled to the electrical contact 522 over connection 534 and to a first terminal of a resistor 542 over connection 536. A first terminal of a resistor 539 is coupled to the electrical contact 524 and to the second terminal of the resistor 542 over connection 543. A first terminal of a resistor 549 is coupled to the electrical contact 548 and to the second terminal of the resistor 542 over connection 543. A first terminal of a resistor 569 is coupled to the electrical contact 568 and to the second terminal of the resistor 542 over connection 543. A first terminal of a resistor 579 is coupled to the electrical contact 578 and to the second terminal of the resistor 542 over connection 543.

In an exemplary embodiment, the voltage source 532 can cause an electrical potential difference to be created between the substrate tap 512 and the substrate taps 514, 544, 564 and 574, creating a P-N junction in the bulk Si 502 between the substrate tap 512 and the substrate taps 514, 544, 564 and 574. In this manner, the P-N junction in the bulk Si 502 between the substrate tap 512 and the substrate taps 514, 544, 564 and 574 can be used to enhance the depletion region 550 in the bulk Si 502 as described above. The initial depletion regions are omitted for simplicity of illustration. The bulk Si 502 is significantly more conductive than the depletion region 550, such that virtually the entire voltage drop occurs across the enhanced depletion region 550.

The bias voltage applied by the voltage source 532 can be adjusted, which together with the difference in Fermi level (Ef) between the substrate taps 514, 544, 564 and 574, or when present the optional contact regions 518, 546, 566, 576, and the bulk Si 502 defines the width of the enhanced depletion region 550. The resistors 542, 539, 549, 569 and 579 can be used minimize the leakage of RF power to the DC bias voltage source 532.

In an exemplary embodiment, the enhanced depletion region 550 comprises a single continuous depletion region associated with the substrate taps 514, 544, 564 and 574, thus creating an extended or elongated enhanced depletion region 550.

In an exemplary embodiment, when circuit components 515, 517 and 519 are placed above the enhanced depletion region 550 created by the electrically biased substrate taps, any non-linear substrate parasitics in the bulk Si 502 are reduced with respect to the previously mentioned substrate treatment methods when sufficient bias voltage is applied.

In an exemplary embodiment, the effect of biasing the substrate taps 512 514, 544, 564 and 574 can be enhanced by, for example, implanting the substrate at the substrate taps 512 514, 544, 564 and 574 to create at one substrate tap (512) a P-type contact region 516 to create an ohmic contact to the bulk Si 502. At the other substrate taps (514, 544, 564 and 574), N-type contact regions 518, 546, 566 and 576 create an ohmic contact to the bulk Si 502.

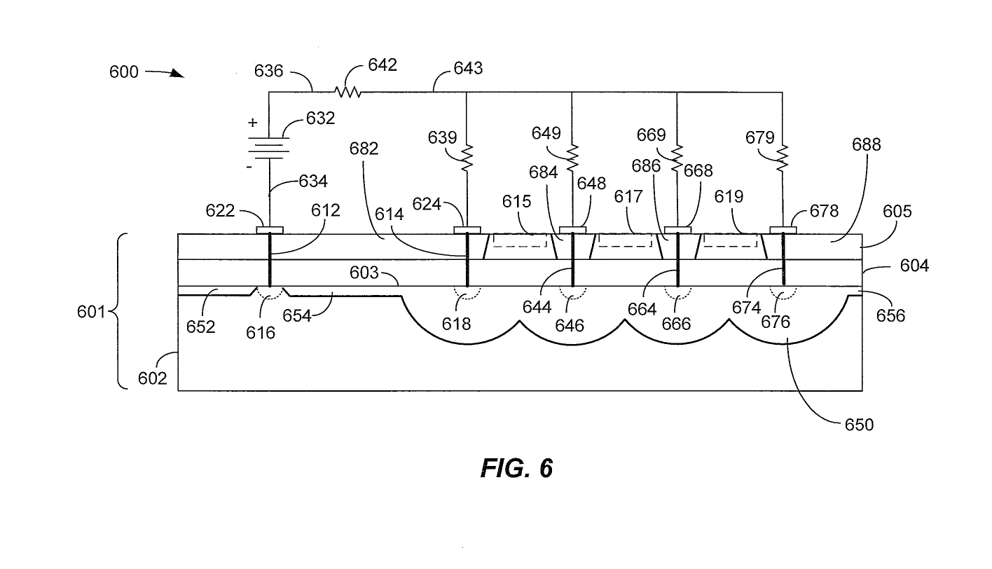

FIG. 6 is a schematic diagram showing an alternative exemplary embodiment of a system for biasing a silicon-on-insulator substrate to enhance a depletion region. In an exemplary embodiment, the system 600 comprises a SOI substrate 601 having a bulk Si layer 602, a buried oxide layer 604 and a device layer 605. The bulk Si 602 can also be referred to as a “handle wafer.” In an exemplary embodiment, the device layer 605 can comprise one or more silicon, metal, or other epitaxial semiconductor material layers that can be deposited, grown, sputtered, or otherwise formed over the surface of the buried oxide layer 604. In an exemplary embodiment, radio frequency (RF) devices 615, 617 and 619 can be fabricated in one or more of the device layers 605. In an exemplary embodiment, isolation regions 682, 684, 686 and 688 can be formed between the devices 615, 617 and 619. In an exemplary embodiment, the isolation regions 682, 684, 686 and 688 can be formed by the STI process described above. This creates isolation regions 682, 684, 686 and 688 through which the substrate taps 612, 614, 644, 664 and 674 may extend. Alternatively, the substrate taps 612, 614, 644, 664 and 674 may also extend through the device layers 605 in areas where there are no isolation regions 682, 684, 686 and 688.

In an exemplary embodiment, the bulk Si 602 can be doped P-type (P−). The buried oxide layer 604 can be formed on the surface 603 of the bulk Si 602 according to techniques known in the art.

In an exemplary embodiment, substrate taps 612, 614, 644, 664 and 674 can be formed in the buried oxide layer 604 as described above. In an exemplary embodiment, the substrate taps 612, 614, 644, 664 and 674 also extend through the isolation regions 682, 684, 686 and 688. In an exemplary embodiment, the substrate taps 612, 614, 644, 664 and 674 can be formed by etching an opening through the isolation regions 682, 684, 686 and 688 and the buried oxide layer 604 down to, or partially past, the interface where the buried oxide layer 604 meets the bulk Si 602 so that the substrate taps 612, 614, 644, 664 and 674 contact the surface 603 of the bulk Si 602.

Optional contact regions 616, 618, 646, 666 and 676 can be formed in the bulk Si 602 proximate to the substrate taps 612, 614, 644, 664 and 674, respectively.

In an exemplary embodiment, the contact region 616 is doped to be P-type and the contact regions 618, 646, 666 and 676 are doped to be N-type. In an exemplary embodiment, the contact region 616 is heavily doped P+ and the contact regions 618, 646, 666 and 676 are heavily doped N+. However, this doping can be reversed depending on implementation

In an exemplary embodiment, the substrate tap 612 is connected to an electrical contact 622, the substrate tap 614 is connected to an electrical contact 624, the substrate tap 644 is connected to an electrical contact 648, the substrate tap 664 is connected to an electrical contact 668, and the substrate tap 674 is connected to an electrical contact 678.

A voltage source 632 is coupled to the electrical contact 622 over connection 634 and to a first terminal of a resistor 642 over connection 636. A first terminal of a resistor 639 is coupled to the electrical contact 624 and to the second terminal of the resistor 642 over connection 643. A first terminal of a resistor 649 is coupled to the electrical contact 648 and to the second terminal of the resistor 642 over connection 643. A first terminal of a resistor 669 is coupled to the electrical contact 668 and to the second terminal of the resistor 642 over connection 643. A first terminal of a resistor 679 is coupled to the electrical contact 678 and to the second terminal of the resistor 642 over connection 643.

In an exemplary embodiment, the voltage source 632 can cause an electrical potential difference to be created between the substrate tap 612 and the substrate taps 614, 644, 664 and 674. In this manner, the P-N junction in the bulk Si 602 between the substrate tap 612 and the substrate taps 614, 644, 664 and 674 can be used to enhance a depletion region in the bulk Si 602 as described above. The initial depletion regions are omitted for simplicity of illustration. The bulk Si 602 is significantly more conductive than the enhanced depletion region 650, such that virtually the entire voltage drop occurs across the enhanced depletion region 650.

The bias voltage applied by the voltage source 632 can be adjusted, which together with the difference in Fermi level (Ef) between the substrate taps, 614, 644, 664, 674, or the optional contact regions 618, 646, 666, 676 when present, and the bulk Si 602 defines the width of the enhanced depletion region 650. The resistors 642, 639, 649, 669 and 679 can minimize the leakage of RF power to the DC bias voltage source 632.

In an exemplary embodiment, the enhanced depletion region 650 comprises a single continuous enhanced depletion region associated with the substrate taps 614, 644, 664 and 674, thus creating an extended, or elongated depletion region 650. In this exemplary embodiment, the enhanced depletion region 650 also comprises additional surface depletion regions 652, 654 and 656. The additional surface depletion regions 652, 654 and 656 can be created at the surface of the bulk Si 602 prior to or just after the formation of the buried oxide layer 604 using the previously mentioned substrate treatment methods.

In an exemplary embodiment, when circuit components 615, 617 and 619 are placed above the enhanced depletion region 650 created by electrically biased substrate taps, any non-linear substrate parasitics are reduced with respect to the previously mentioned substrate treatment methods when sufficient bias voltage is applied.

In an exemplary embodiment, the effect of biasing the substrate taps 612, 614, 644, 664 and 674 can be enhanced by, for example, implanting the substrate at the substrate taps 612 614, 644, 664 and 674 to create at one substrate tap (612) a P-type contact region 616 to create an ohmic contact to the bulk Si 602. At the other substrate taps 614, 644, 664 and 674, N-type contact regions 618, 646, 666 and 676 create an ohmic contact to the bulk Si 602.

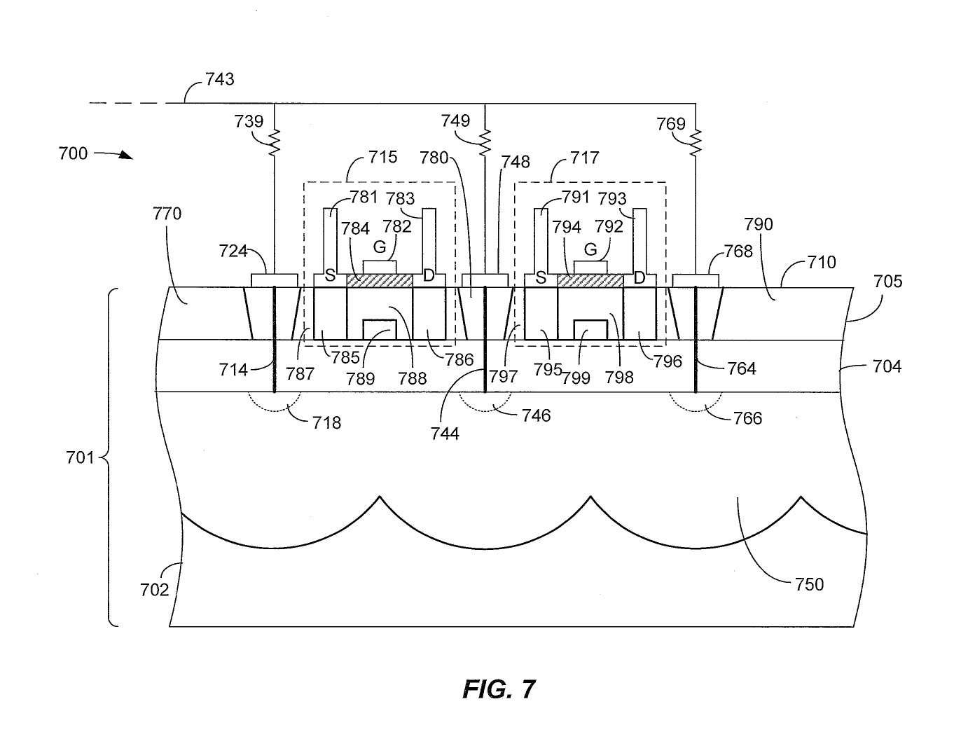

FIG. 7 is a schematic diagram showing an exemplary embodiment of a system for biasing a silicon-on-insulator substrate to enhance a depletion region including semiconductor devices. In an exemplary embodiment, the system 700 comprises a silicon (Si) substrate 701 having a bulk Si layer 702, a buried oxide layer 704 and device layers 705. In an exemplary embodiment, the device layers 705 can comprise one or more epitaxial semiconductor material layers that can be deposited, grown, sputtered, or otherwise formed over the surface of the buried oxide layer 704. In an exemplary embodiment, radio frequency (RF) devices 715 and 717 can be fabricated in one or more of the device layers 705. In an exemplary embodiment, many tens or hundreds of RF devices can be fabricated as a two-dimensional array over a surface 710 of the uppermost device layer 705.

The bulk Si 702 can be similar to the bulk SI 502 and 602 described herein. In FIG. 7, the substrate 701 illustrates only a portion of the substrate 501 and the substrate 601 described above.

In an exemplary embodiment, substrate taps 714, 744 and 764 are shown for reference relative to the devices 715 and 717. The substrate taps 714, 744 and 764 are similar to the substrate taps 514, 544 and 564; and the substrate taps 614, 644 and 664. In an exemplary embodiment, the substrate taps 714, 744 and 764 extend through the isolation regions 770, 780, and 790. Optional contact regions 718, 746 and 766 can be formed in the bulk Si 702 proximate to the substrate taps 714, 744 and 764, respectively.

In an exemplary embodiment, the substrate tap 714 is connected to an electrical contact 724, the substrate tap 744 is connected to an electrical contact 748 and the substrate tap 764 is connected to an electrical contact 768.

A voltage source (not shown) is coupled to the connection 743 to provide a bias voltage to the substrate taps 714, 744 and 764, through respective resistors 739, 749 and 769, as described above.

The bias voltage applied by the voltage source (not shown) can be adjusted to create the enhanced depletion region 750, as described above. In this exemplary embodiment, the enhanced depletion region 750 comprises a single continuous depletion region associated with the substrate taps 714, 744 and 764, thus creating an extended, or elongated enhanced depletion region 750.

In an exemplary embodiment, the circuit components 715 and 717 may comprise RF devices, switches, capacitances, or other RF or non-RF switch components that can be placed above the depletion region 750 created by electrically biased substrate taps.

In an exemplary embodiment, the circuit component 715 may comprise a field effect transistor (FET) device having a source 781, a gate 782 and a drain 783, formed using electrically conductive material, such as a metal. The circuit component 715 also comprises a gate oxide 784, an N+ region 785 corresponding to the source of the circuit component 715 and an N+ region 786 corresponding to the drain of the circuit component 715 formed in a portion 787 of the device layers 705. A local depletion region 788 may be created between the N+ source region 785 and the N+ drain region 786 based on the electrical parameters applied to the gate 782, source 781 and drain 783. An optional back gate 789 may also be formed in the portion 787 of the device layers 705.

In an exemplary embodiment, the circuit component 717 may comprise a field effect transistor (FET) device having a source 791, a gate 792 and a drain 793, formed using electrically conductive material, such as a metal. The circuit component 717 also comprises a gate oxide 794, an N+ region 795 corresponding to the source of the circuit component 717 and an N+ region 796 corresponding to the drain of the circuit component 717 formed in a portion 797 of the device layers 705. A local depletion region 798 may be created between the N+ source region 795 and the N+ drain region 796 based on the electrical parameters applied to the gate 792, source 791 and drain 793. An optional back gate 799 may also be formed in the portion 797 of the device layers 705.

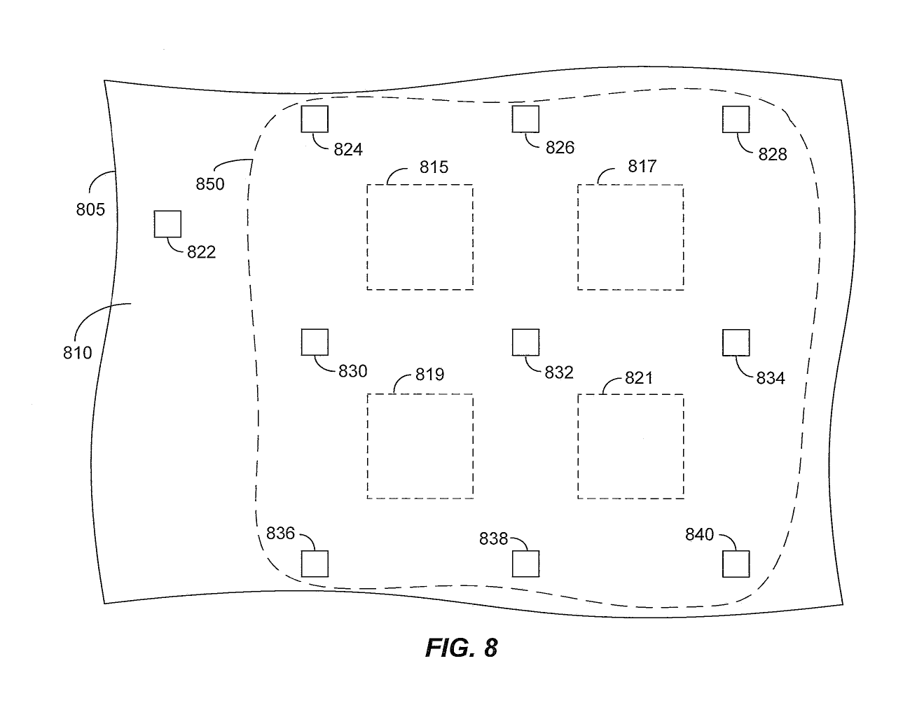

FIG. 8 is a plan view showing a surface of an uppermost device layer of FIG. 7. In an exemplary embodiment, the uppermost of the device layers 805 includes a surface 810. The surface 810 includes a plurality of RF devices 815, 817, 819 and 821; and a plurality of contacts 822, 824, 826, 828, 830, 832, 834, 836, 838 and 840 arrayed over the surface 810. Each of the contacts 822, 824, 826, 828, 830, 832, 834, 836, 838 and 840 may include an associated substrate tap as described above to establish a depletion region 850 below the RF devices 815, 817, 819 and 821 as described above. The isolations regions are not shown for simplicity.

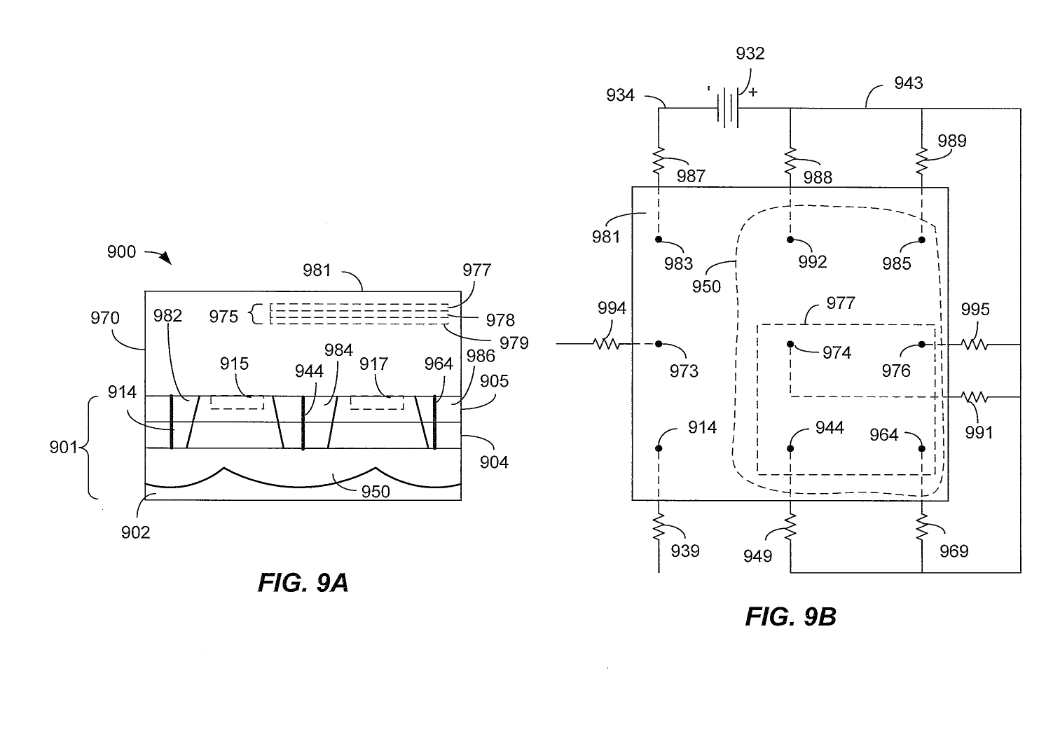

FIG. 9A is a schematic diagram showing an alternative exemplary embodiment of a system for biasing a silicon-on-insulator substrate.

In an exemplary embodiment, the system 900 comprises a silicon (Si) substrate 901 having a bulk Si layer 902, a buried oxide layer 904 and device layers 905. In an exemplary embodiment, the device layers 905 can comprise one or more epitaxial semiconductor material layers that can be deposited, grown, sputtered, or otherwise formed over the surface of the buried oxide layer 904. In an exemplary embodiment, radio frequency (RF) devices 915 and 917 can be fabricated in one or more of the device layers 905. In an exemplary embodiment, additional material layers 970 can be formed over the device layers 905. In an exemplary embodiment, the additional material layers 970 may comprise metal layers, insulating layers, and other layers.

The bulk Si 902 can be similar to the bulk Si 502, 602 and 702 described herein. In FIG. 9A, the substrate 901 illustrates only a portion of the substrate 501, 601 and 701 described above.

In an exemplary embodiment, substrate taps 914, 944 and 964 are shown for reference relative to the devices 915 and 917. The substrate taps 914, 944 and 964 are similar to the substrate taps 514, 544 and 564; and the substrate taps 614, 644 and 664 and the substrate taps 714, 744 and 764. In an exemplary embodiment, the substrate taps 914, 944 and 964 extend through the isolation regions 982, 984 and 986.

The electrical contacts, resistors and voltage source coupled to the substrate taps 914, 944 and 964 are omitted from FIG. 9A for simplicity.

The bias voltage applied by the voltage source (not shown) can be adjusted to create the enhanced depletion region 950, as described above. In this exemplary embodiment, the enhanced depletion region 950 comprises a plurality of elongated overlapping depletion regions associated with the substrate taps 914, 944 and 964, thus creating an elongated enhanced depletion region 950 as described above with respect to FIG. 7.

In an exemplary embodiment, additional circuit structures can be formed in the additional material layers 970 over one or more of the substrate taps 914, 944 and 964. In an exemplary embodiment, a structure 975 may be, for example, a MIM (metal-insulator-metal) capacitor comprising a first metal element 977 and a second metal element 979 separated by a dielectric (or other insulating) material 978. In an exemplary embodiment, the first metal element 977, second metal element 979 and dielectric material 978 can be formed in three layers of the additional material layers 970.

In an exemplary embodiment, the structure 975 may be formed over the substrate taps 944 and 964 so that the structure 975 overlaps the depletion region 950.

FIG. 9B is a schematic diagram showing a plan view of the exemplary embodiment of the system for biasing a silicon-on-insulator substrate to enhance a depletion region of FIG. 9A. The top surface of the first metal element 977 is shown in phantom below the surface 981 of the additional material layers 970. Substrate taps 914, 944, 964, 973, 974, 976, 983, 992 and 985 are also shown as an array below the surface 981. The substrate tap 914 is coupled to a resistor 939, the substrate tap 944 is coupled to a resistor 949, and the substrate tap 964 is coupled to a resistor 969. Similarly, the substrate taps 973, 974, 976, 983, 992 and 985 are coupled to respective resistors 994, 991, 995, 987, 988 and 989. In this exemplary embodiment, a voltage source 932 is coupled to the resistor 987 over connection 934, and to the resistors 988, 989, 995, 991, 949 and 969 over connection 943.

In an exemplary embodiment, a bias voltage applied by the voltage source 932 can be adjusted to create the depletion region 950, as described above. In this exemplary embodiment, the depletion region 950 comprises a plurality of overlapping depletion regions associated with the substrate taps 944, 964, 974, 976, 992 and 985, thus creating the depletion region 950 over which the structure 975 can be formed.

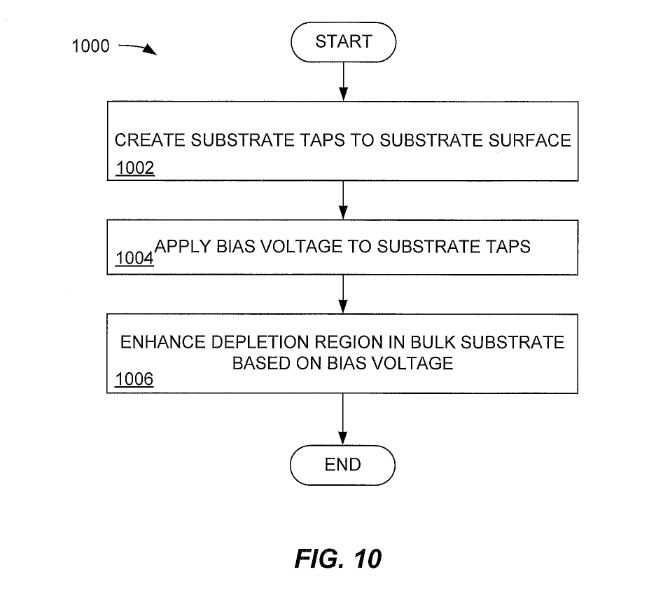

FIG. 10 is a flow chart showing an exemplary embodiment of a method for biasing a silicon-on-insulator substrate to enhance a depletion region.

In block 1002, substrate taps are created to a surface of a bulk Si substrate.

In block 1004, a bias voltage is applied to the bulk Si substrate through the substrate taps.

In block 1006, a depletion region is enhanced in the bulk Si substrate below the substrate taps.

Biasing a silicon-on-insulator substrate to enhance a depletion region as described herein may be implemented on one or more ICs, analog ICs, RFICs, mixed-signal ICs, ASICs, printed circuit boards (PCBs), electronic devices, etc. Biasing a silicon-on-insulator substrate to enhance a depletion region may also be implemented with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

Biasing a silicon-on-insulator substrate to enhance a depletion region as described herein may be implemented in a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

Although selected aspects have been illustrated and described in detail, it will be understood that various substitutions and alterations may be made therein without departing from the spirit and scope of the present invention, as defined by the following claims.

What is claimed is:

1. A device, comprising:
a silicon-on-insulator (SOI) substrate comprising a bulk silicon (Si) substrate, a buried oxide layer over the bulk Si substrate and a silicon device layer over the buried oxide layer;
a first substrate tap and a second substrate tap located in the buried oxide layer and the silicon device layer, the first and second substrate taps in contact with the bulk Si substrate; and
an initial depletion region located in the bulk Si substrate below the buried oxide layer and associated with at least one of the first substrate tap and the second substrate tap, the first substrate tap and the second substrate tap configured to increase the initial depletion region based on an applied bias voltage.

2. The device of claim 1, wherein a plurality of increased depletion regions form a continuous extended depletion region.

3. The device of claim 1, wherein the first substrate tap and the second substrate tap are formed using any of a metal, a silicon and a polysilicon material.

4. The device of claim 3, wherein the metal is chosen from aluminum, copper, chromium, tungsten and titanium.

5. The device of claim 3, wherein the polysilicon is doped polysilicon.

6. The device of claim 3, wherein the first substrate tap and the second substrate tap create rectifying contact to the bulk Si substrate.

7. The device of claim 2, further comprising a radio frequency device located over the continuous extended depletion region.

8. The device of claim 1, wherein the bulk Si substrate further comprises a first contact region in electrical contact with the first substrate tap and a second contact region in electrical contact with the second substrate tap.

9. The device of claim 8, wherein a plurality of increased depletion regions form a continuous extended depletion region.

10. The device of claim 8, wherein the electrical contact between the substrate tap and the semiconductor contact region is an ohmic contact.

11. The device of claim 8, wherein at least one of the first contact region and the second contact region is doped opposite a doping of the bulk Si substrate.

12. The device of claim 8, wherein the first substrate tap and the second substrate tap are formed using any of a metal, a silicon and a polysilicon material.

13. The device of claim 12, wherein the metal is chosen aluminum, copper, chromium, tungsten and titanium.

14. The device of claim 12, wherein the polysilicon is doped polysilicon.

15. The device of claim 9, further comprising a radio frequency device located over the continuous extended depletion region.

16. A method comprising:
biasing a bulk Si substrate through substrate taps in contact with the bulk Si substrate; and
increasing an initial depletion region to form an enhanced depletion region in the bulk Si.

17. The method of claim 16, wherein a plurality of enhanced depletion regions form a continuous extended depletion region.

18. The method of claim 16, further comprising locating a radio frequency device located over the enhanced depletion region.

19. A device, comprising:
means for biasing a bulk Si substrate through substrate taps in contact with the bulk Si substrate; and
means for increasing an initial depletion region to form an enhanced depletion region in the bulk Si.

20. The device of claim 19, further comprising means for forming a continuous extended depletion region in the bulk Si.
